(19) United States
(12) Patent Application Publication
(10) Pub. No.: US 2018/0332712 A1
(43) Pub. Date: Nov. 15, 2018

(54) HIGH-RESOLUTION PRINTING TECHNIQUE

(71) Applicant: CARPE DIEM TECHNOLOGIES, INC., Franklin, MA (US)

(72) Inventor: John S. Berg, Mattapoisett, MA (US)

(21) Appl. No.: 15/977,260

(22) Filed: May 11, 2018

Related U.S. Application Data
(60) Provisional application No. 62/504,998, filed on May 11, 2017.

(51) Int. Cl. H05K 3/12; B41M 3/00

(52) U.S. Cl. CPC H05K 3/125; H05K 3/1208; H05K 2203/0779; H05K 2203/013; B41M 3/006

(57) ABSTRACT

A miniature technological structure is fabricated by printing a conductive ink in a highly precise pattern onto a substrate. In one embodiment, high-resolution printing of the conductive ink is achieved by precisely patterning a hydrophobic, ink-repellant layer onto a print-receptive surface on the substrate. A water-based, conductive ink is then broadly applied to the substrate, with the ink adhering to the exposed print-receptive surfaces on the substrate and repelling from the ink-repellant layer. In this manner, the ink-repellant layer functions as mask which defines the pattern of the conductive ink retained on the substrate. Because the hydrophobic, ink-repellant layer can be printed with relatively great precision, nanoscale structures can be achieved. In lieu of applying a separate hydrophobic layer onto the substrate, hydrophobicity can be imparted onto an otherwise ink-receptive surface in the desired masking pattern, for example, by roughening the physical texture of the surface.

### FIELD OF THE INVENTION

The present invention relates generally to the fabrication of miniature structures and, more particularly, to the printing of miniature structures onto designated substrates.

### BACKGROUND OF THE INVENTION

Miniature electrical structures, such as integrated circuits, are often fabricated by printing a conductive ink in a predefined pattern onto a print-receptive surface of a designated substrate. In the art, the fabrication of miniaturized technological structures is commonly referred to as microfabrication when used to manufacture structures measured in microns (10⁻⁶ m) and nanofabrication when used to manufacture structures measured in nanometers (10⁻⁹ m) or smaller. As can be appreciated, it has been found that the size of miniaturized structures is often limited by constraints associated with the aforementioned printing process.

Specifically, the resolution and accuracy of miniature printed patterns are largely limited by, among other things, ink drop size, the extent that an ink drop spreads on a particular substrate, as well as the spacing between adjacent ink drops. Furthermore, it has been found that current nanoparticle and functionalized inks are difficult to jet in a reliable fashion, particularly on certain substrates. Notably, such inks are non-Newtonian fluids and, such, do not flow evenly through relatively small orifices, resulting in the occluding and clogging of printer nozzles.

Accordingly, it has been found that resolution limitations experienced when printing miniature patterns result in unacceptable yields. For instance, in printed microelectronics, the over-dispensing of ink creates short circuits, whereas the under-dispensing of ink creates open circuits.

### SUMMARY OF THE INVENTION

It is an object of the invention to provide a new and improved method for printing miniature technological structures on a designated surface.

It is another object of the present invention to provide a method for printing miniature technological structures on a designated surface with a relatively high degree of resolution and accuracy.

It is yet another object of the present invention to provide a method as described above that can be easily implemented in an efficient and cost-effective fashion.

Accordingly, as a feature of the present invention, there is provided a method of printing a miniature conductive pattern onto a substrate, the substrate having a print-receptive surface, the method comprising the steps of (a) depositing an ink-repellant layer onto the print-receptive surface, the ink-repellant layer being patterned with voids that define a set of exposed regions in the print-receptive surface, and (b) applying ink onto the substrate, the ink adhering to the set of exposed regions in the print-receptive surface, the ink repelling from the ink-repellant layer, (c) wherein the ink which adheres to the exposed regions in the print-receptive surface defines the miniature conductive pattern.

As another feature of the present invention, there is provided a method of printing a miniature conductive pattern onto a substrate, the substrate having a surface, the method comprising the steps of (a) treating the surface of the substrate to include a print-receptive region and an ink-repellant region, the print-receptive region having a pattern, and (b) applying ink onto the surface of the substrate, the ink adhering to print-receptive region, the ink repelling from the ink-repellant layer, (c) wherein the ink which adheres to the print-receptive surface defines the miniature conductive pattern.

Various other features and advantages will appear from the description to follow. In the description, reference is made to the accompanying drawings which form a part thereof, and in which is shown by way of illustration, an embodiment for practicing the invention. The embodiment will be described in sufficient detail to enable those skilled in the art to practice the invention, and it is to be understood that other embodiments may be utilized and that structural changes may be made without departing from the scope of the invention. The following detailed description is therefore, not to be taken in a limiting sense, and the scope of the present invention is best defined by the appended claims.

### BRIEF DESCRIPTION OF THE DRAWINGS

In the drawings, wherein like reference numerals represent like parts:

FIGS. 1(a)-(d) are a series of section views of a miniature technological structure at various stages during its manufacture using a first high-resolution printing technique described in detail herein in accordance with the teachings of the present invention; and

FIGS. 2(a)-(d) are a series of section views of a miniature technological structure at various stages during its manufacture using a second high-resolution printing technique described in detail herein in accordance with the teachings of the present invention.

### DETAILED DESCRIPTION OF THE INVENTION

### High Resolution Printing Technique

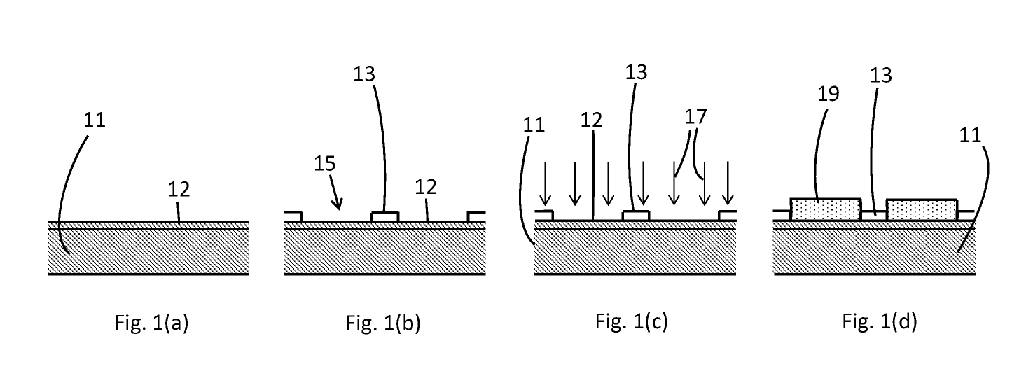

Referring now to FIGS. 1(a)-(d), there is shown a series of section views of a miniature technological structure at various stages during its manufacture using a novel high-resolution printing technique described in detail herein in accordance with the present invention. As will be explained in detail below, high-resolution printing is achieved by precisely patterning a layer that is unreceptive to ink on the designated surface of the object to be printed. In this manner, print accuracy is defined by the resolution that can be realized from the layer unreceptive to ink rather than the printed ink itself.

For simplicity purposes only, the printing technique of the present invention will be described herein in the manufacture of a miniature technological structure, such as an integrated circuit (IC) formed on a suitable substrate. However, it is to be understood that the printing technique of the present invention is not limited to any particular printed product or size thereof.

Referring now to FIG. 1, a suitable substrate 11 is provided on which the printing technique, or method, of the present invention is performed. In the present embodiment, substrate 11 is a polymer material, such as polyamide or polyethylene terephthalate (PET). Due to its inherent hydrophobic properties, the entire print-designated surface of substrate 11 is preferably pretreated to be hydrophilic, for example, through a suitable ultraviolet, corona or plasma treatment. As a result of the treatment, substrate 11 includes an exposed outer surface 12 that is highly print-receptive and therefore readily promotes adhesion of inks thereto.

Upon completion of the pretreatment of substrate 11, a hydrophobic, or super hydrophobic, layer 13 is precisely patterned onto surface 12 so as to define voids, or recesses, 15 therebetween, as represented in FIG. 1(b). As can be appreciated, voids 15 expose regions of print-receptive surface 12 in the precise trace pattern for the desired miniature technological structure (e.g., printed IC). In this capacity, the pattern of layer 13 effectively serves as a negative for the desired trace pattern to be printed on substrate 11.

Layer 13 represents any suitable material that is both unreceptive to a water-based ink (i.e. print-repellant) and, in turn, able to be patterned on substrate 11 with relatively high resolution. As defined herein, hydrophobic layer 13 encompasses both hydrophobic and superhydrophobic materials. For instance, layer 13 may be formed using a silane reagent, such as the Aquaphobe® line of water-repellant materials manufactured by Gelest, Inc., of Morrisville, Pa.

The patterned deposition of hydrophobic layer 13 onto surface 12 of substrate 11 can be accomplished using any suitable technique.

As an example, hydrophobic layer 13 could be deposited onto surface 12 of substrate 11 using an appropriately patterned mask.

As another example, hydrophobic layer 13 could be deposited onto surface 12 of substrate 11 using inkjet technology currently utilized in the patterned printing of nanoparticle-filled inks to create miniature technological structures (e.g., microcircuits). In other words, a hydrophobic material would be dispensed, or patterned, from an inkjet printer instead of a conductive ink. Furthermore, due to its relatively low viscosity, the hydrophobic material can be jet by the printer with greater resolution and less risk of occlusion than traditional inks. Lastly, while the settings for inkjet printers are commonly adjusted to compensate for the different characteristics of various types of nanomaterials and inks printed therefrom, the patterned printing of a single, constant, hydrophobic material would enable the inkjet printer to be specifically tuned, or adjusted, for optimized performance, which is highly desirable.

As yet another example, hydrophobic layer 13 could be deposited onto the entirety of print-receptive layer 12. Thereafter, the hydrophobicity of layer 13 could be selectively altered, or destroyed, (e.g. using an ultraviolet (UV), or otherwise activating, laser or UV patterning techniques) in the precise pattern for the miniature structure. As a result, a wetting path in the desired pattern is formed in hydrophobic layer 13 that renders it receptive to conductive ink 17.

As seen most clearly in FIG. 1(c), with print-repellant layer 13 deposited in the manner set forth above, a conductive ink 17 is applied over the entire print-designated area of substrate 11, including the exposed regions of print-receptive layer 12 as well as the portions of print-receptive layer 12 covered by hydrophobic layer 13.

Ink 17 represents any conductive, water-based ink, such as a silver ink. As can be appreciated, ink 17 readily adheres to the exposed regions of print-receptive layer 12. By contrast, water-based ink 17 is repelled by hydrophobic layer 13. This distinction in adherence properties enables ink 17 to be broadly applied, or coated, over the entire print-designated area of substrate 11 in a highly efficient fashion. For instance, ink 17 may be applied using, inter alia, a spray coat system, a rotogravure printing process, or even an inkjet printer that utilizes a relatively large drop size.

As a result of the steps set forth above, a conductive ink pattern 19 is formed on substrate 11 that is limited to voids 15 within hydrophobic layer 13, as shown in FIG. 1(d). As can be appreciated, conductive ink pattern 19 represents the desired miniature technological structure fabricated through the high-resolution printing process described in detail above.

As referenced briefly above, the resolution of pattern 19 is defined by the inherent accuracy in patterning ink-repellant layer 13 onto substrate 11. Due to certain inherent characteristics of the material used to form layer 13 (e.g. viscosity), it has been found that considerable precision can be achieved in forming conductive pattern 19.

### Features and Advantages of the Present Invention

The printing technique described in detail above affords a number of notable advantages in the manufacture of miniature technological structures.

As a first advantage, the resolution of pattern 19 is defined primarily by the accuracy in patterning ink-repellant layer 13 onto surface 12 of substrate 11. Furthermore, it has been found that the particular material utilized for layer 13 can be applied onto substrate 11 with great precision. As a result, considerable precision can be achieved in creating conductive pattern 19.

As a second advantage, because the resolution of pattern 19 is defined primarily by the accuracy in patterning ink-repellant layer 13 onto surface 12 of substrate 11, the characteristics of the particular ink 17 utilized to form conductive pattern 19 would have a limited effect on the overall resolution of the printed pattern 19. As a result, the printing technique of the present invention allows for the creation of highly precise printing patterns (e.g., microscale or nanoscale patterns) using inks that were previously considered suboptimal, or even problematic, in such applications.

### Alternate Embodiments and Design Modifications

The high-resolution printing method described in detail above is intended to be merely exemplary and those skilled in the art shall be able to make numerous variations and modifications to it without departing from the spirit of the present invention. All such variations and modifications are intended to be within the scope of the present invention as defined in the appended claims.

As an example, it should be noted that ink 17 need not be limited to a conductive-type ink. Rather, it is to be understood that ink 17 represents any type of ink that could be used in the patterning of miniature structures. For instance, conductive ink 17 encompasses, inter alia, semiconductive inks (e.g., silicon nanoparticle inks) which are used to create miniature structures, such as transistors and solar cells.

As another example, it should be noted that ink 17 need not be a water-based ink. Rather, if ink-repellant layer 13 is formed using an oleophobic (i.e. oil-repellant) material, instead of a water-repellant material, an oil-based ink could be utilized to create the miniature technological structure.

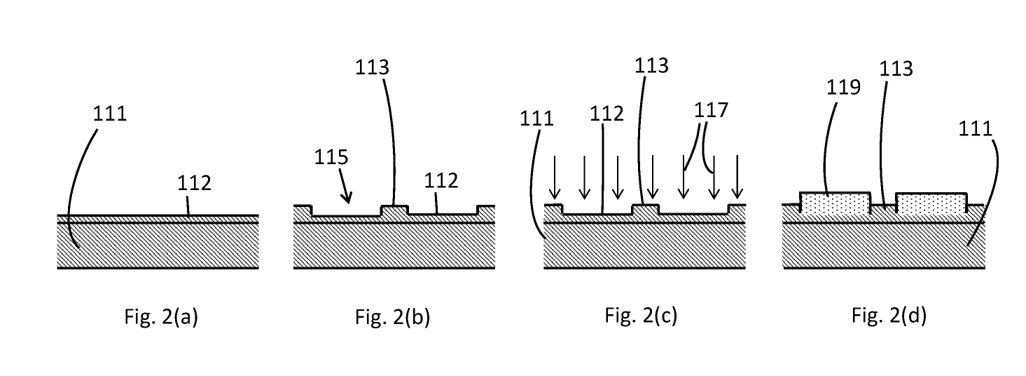

As yet another example, selective hydrophobicity could be imparted onto substrate 11 without the application of a patterned ink-repellant layer 13. For instance, referring now to FIGS. 2(a)-(d), there is shown a series of section views of a miniature technological structure at various stages of its manufacture using an alternative high-resolution printing technique described in detail herein in accordance with the present invention.

As shown in FIG. 2(a), a substrate 111 with a print-receptive surface 112 is provided on which the printing technique of the present invention is performed. Preferably, substrate 111 is similar to substrate 11 in that substrate 111 is a polymer material, such as polyamide or PET.

However, in lieu of the application of an ink-repellant material, the present method is designed to impart print-receptive surface 112 of substrate 11 with a uniquely patterned surface roughness (or some other unique physical texture) 113 that defines undisturbed portions, or voids, 115 therein in the designated structure pattern, as shown in FIG. 2(b). In this manner, the roughened, or textured, portions 113 of surface 112 would not be receptive to ink, whereas the non-textured portions of surface 112 (i.e. within voids 115) would remain print-receptive.

Strictly for simplicity of illustration, roughened portions 113 are represented herein as being raised slightly above undisturbed portions 115. However, it is to be understood that roughened portions 113 could lie either generally coplanar with or beneath undisturbed portions 115 without departing from the spirit of the present invention.

As shown in FIG. 2(c), a conductive, water-based ink 117 is then applied over the entirety of surface 112, both on textured portions 113 as well as within voids 115. Due to the inherent differences in hydrophobicity along surface 112, ink 117 readily adheres to surface 112 within undisturbed portions 115 but, by contrast, is repelled by surface 112 within roughened portions 113.

As a result of the steps set forth above, a conductive ink pattern 119 is formed on substrate 111 that is limited to undisturbed portions 115, as shown in FIG. 2(d). Effectively, textured portions 113 function as a mask for printing miniature patterns, with the resolution of pattern 119 defined by the inherent precision in forming textured portions 113. It is envisioned that the above-described process is capable of patterning textured portions 113 on surface 112 at nanoscale or microscale levels using, inter alia, nanoimprint lithography. As a result, the aforementioned printing technique is well-suited for use in the fabrication of very small technological structures, which is highly desirable.

What is claimed is:

1. A method of printing a miniature conductive pattern onto a substrate, the substrate having a print-receptive surface, the method comprising the steps of:
(a) depositing an ink-repellant layer onto the print-receptive surface, the ink-repellant layer being patterned with voids that define a set of exposed regions in the print-receptive surface; and
(b) applying ink onto the substrate, the ink adhering to the set of exposed regions in the print-receptive surface, the ink repelling from the ink-repellant layer;
(c) wherein the ink which adheres to the exposed regions in the print-receptive surface defines the miniature conductive pattern.

2. The method as claimed in claim 1 wherein the ink is a conductive ink.

3. The method as claimed in claim 2 wherein the ink is a water-based, conductive ink.

4. The method as claimed in claim 3 wherein the ink-repellant layer is a hydrophobic layer of material.

5. The method as claimed in claim 4 wherein the hydrophobic layer of material comprises a silane reagent.

6. The method as claimed in claim 4 wherein, in the depositing step, the ink-repellant layer is deposited onto the print-receptive surface through a patterned mask.

7. The method as claimed in claim 4 wherein, in the depositing step, the ink-repellant layer is deposited onto the print-receptive surface using an inkjet printer.

8. The method as claimed in claim 2 wherein the ink is an oil-based ink.

9. The method as claimed in claim 8 wherein the ink-repellant layer is an oleophobic layer of material.

10. A method of printing a miniature conductive pattern onto a substrate, the substrate having a surface, the method comprising the steps of:
(a) treating the surface of the substrate to include a print-receptive region and an ink-repellant region, the print-receptive region having a pattern; and
(b) applying ink onto the surface of the substrate, the ink adhering to print-receptive region, the ink repelling from the ink-repellant layer;
(c) wherein the ink which adheres to the print-receptive surface defines the miniature conductive pattern.

11. The method of claim 10 wherein the ink is a conductive ink.

12. The method of claim 11 wherein the ink is a water-based, conductive ink.

13. The method of claim 12 wherein, in the treating step, the surface of the substrate is applied with a hydrophobic layer that defines the pattern of the print-receptive region.

14. The method of claim 13 wherein the hydrophobic layer comprises a silane reagent.

15. The method of claim 12 wherein, in the treating step, the surface of the substrate is applied with a hydrophobic layer, wherein portions of the hydrophobic layer are selectively altered to become print-receptive in the pattern of the print-receptive region.

16. The method of claim 15 wherein the hydrophobic layer comprises a silane reagent.

17. The method of claim 11 wherein the ink is an oil-based ink.

18. The method of claim 17 wherein, in the treating step, the surface of the substrate is applied with an oleophobic layer that defines the pattern of the print-receptive region.

19. The method of claim 17 wherein, in the treating step, the surface of the substrate is applied with an oleophobic layer, wherein portions of the oleophobic layer are selectively altered to become print-receptive in the pattern of the print-receptive region.
